(19) United States
(12) Patent Application Publication
(10) Pub. No.: US 2026/0090058 A1
(43) Pub. Date: Mar. 26, 2026

(54) SEMICONDUCTOR DEVICE

(71) Applicant: HON HAI PRECISION INDUSTRY CO., LTD., New Taipei City (TW)

(72) Inventors: Jhe-Hao CHANG, Hsinchu City (TW); Jheng-Sheng YOU, Hsinchu City (TW)

(21) Appl. No.: 18/967,598

(22) Filed: Dec. 3, 2024

(30) Foreign Application Priority Data
Sep. 24, 2024 (TW) 113136236

(51) Int. Cl. H10D 64/23

(52) U.S. Cl. CPC H10D 64/256; H10D 64/258

(57) ABSTRACT

A semiconductor device includes a substrate structure, a source structure, a drain structure, and a gate structure. The source structure, the drain structure, and the gate structure are over the substrate structure and arranged along a first direction. The drain structure includes multiple first electrode units and multiple second electrode units. Each of the first electrode units includes a p-type semiconductor layer and a first metal electrode over the p-type semiconductor layer. Each of the second electrode units includes a second metal electrode. The first and second electrode units are arranged alternately along a second direction that is substantially perpendicular to the first direction. A width of the p-type semiconductor layer of each of the first electrode units along the first direction is substantially equal to a width of the second metal electrode of each of the second electrode units along the first direction.

### CROSS-REFERENCE TO RELATED APPLICATION

This application claims priority to Taiwan Application Serial Number 113136236, filed September 24, 2024, which is herein incorporated by reference in its entirety.

### BACKGROUND

### TECHNICAL FIELD

The present disclosure relates to a semiconductor device.

### DESCRIPTION OF RELATED ART

III-V compound semiconductors are widely used in integrated circuit components, such as high power field-effect transistors (FET), high frequency transistors, high electron mobility transistors (HEMT), or the like, due to their semiconductor properties. Among high electron mobility transistors, gallium nitride-based materials have received special attention in recent years due to their wide band gap, high saturation rate, and suitability for high frequency and high power density operations. However, in order to improve the device reliability, it is necessary to further increase the breakdown voltage of high electron mobility transistors.

### SUMMARY

According to an embodiment of the disclosure, a semiconductor device includes a substrate structure, a source structure, a drain structure, and a gate structure. The substrate structure includes a semiconductor layer. The source structure is over the semiconductor layer of the substrate structure. The drain structure is over the semiconductor layer and arranged along a first direction with the source structure. The drain structure includes a plurality of first electrode units and a plurality of second electrode units. Each of the first electrode units includes a p-type semiconductor layer and a first metal electrode over the p-type semiconductor layer. Each of the second electrode units includes a second metal electrode. The first electrode units and the second electrode units are arranged alternately along a second direction. The second direction is substantially perpendicular to the first direction. A width of the p-type semiconductor layer of each of the first electrode units along the first direction is substantially equal to a width of the second metal electrode of each of the second electrode units along the first direction. The gate structure is over the semiconductor layer and between the source structure and the drain structure.

### BRIEF DESCRIPTION OF THE DRAWINGS

FIG. 1 is a top view of a semiconductor device according to some embodiments of the present disclosure;

FIG. 2, FIG. 3, and FIG. 4 are partial cross-sectional views of a semiconductor device according to some embodiments of the present disclosure;

FIG. 5 is a schematic diagram of an equivalent circuit model of a semiconductor device according to some embodiments of the present disclosure;

FIG. 6 is a partial cross-sectional view of a semiconductor device according to some other embodiments of the present disclosure; and

FIG. 7 is a partial cross-sectional view of a semiconductor device according to still some other embodiments of the present disclosure.

### DETAILED DESCRIPTION

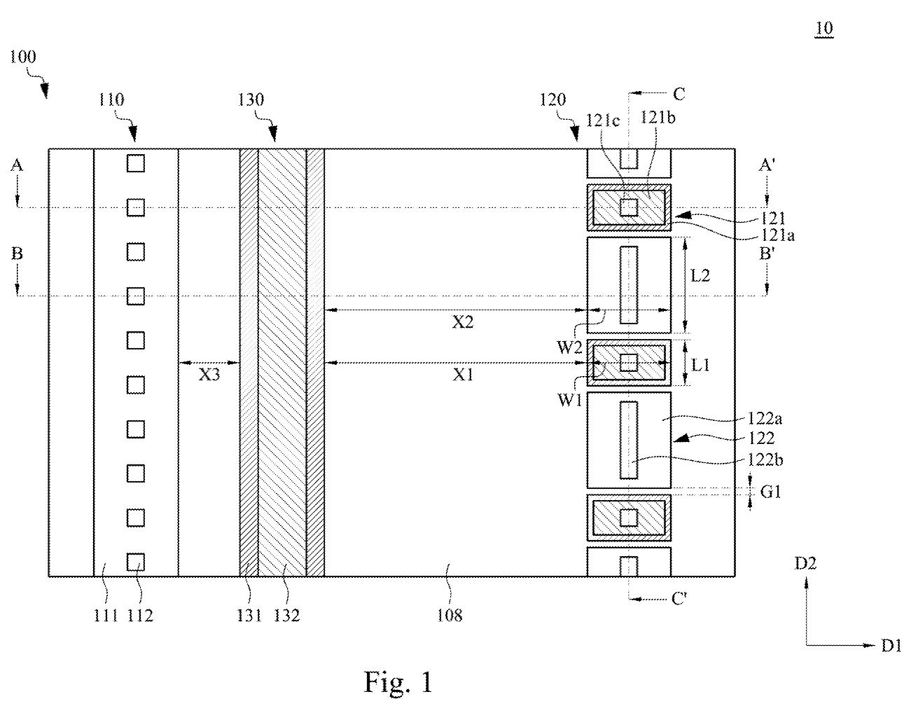

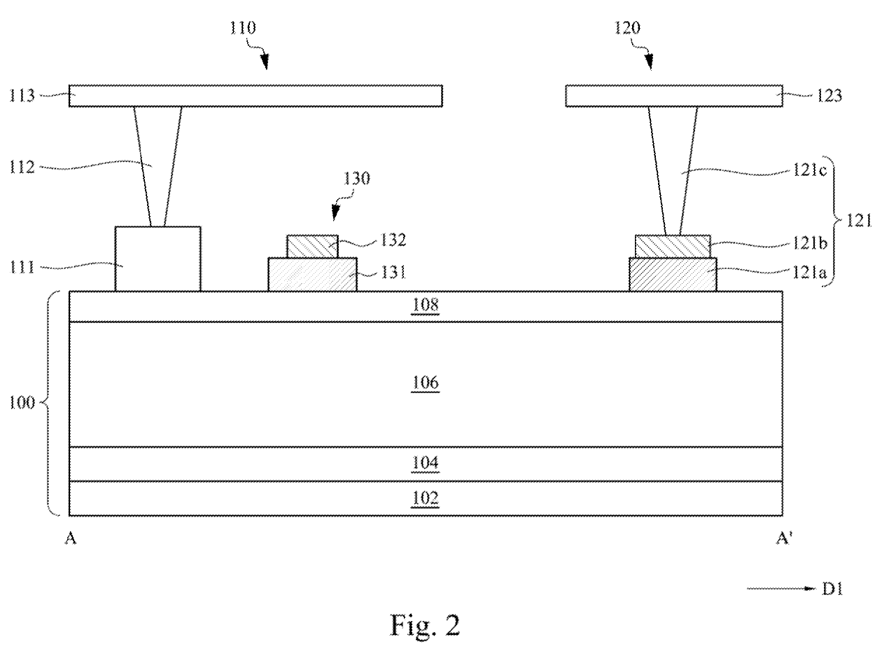

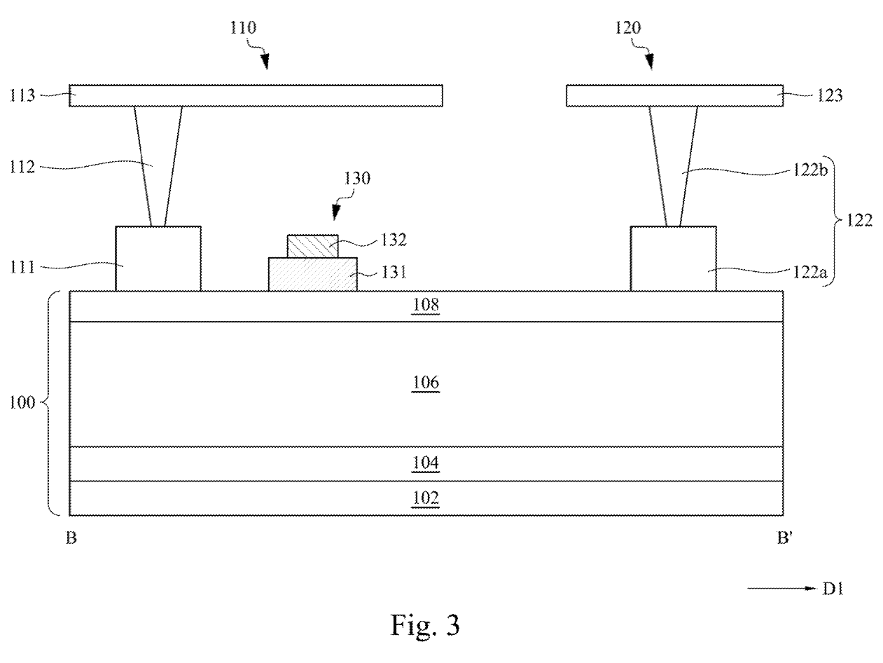

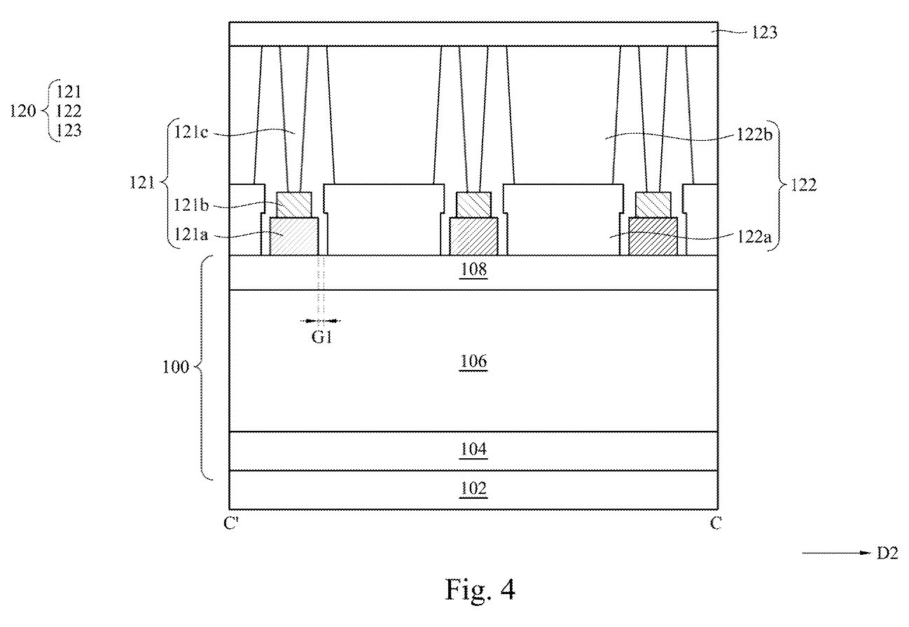

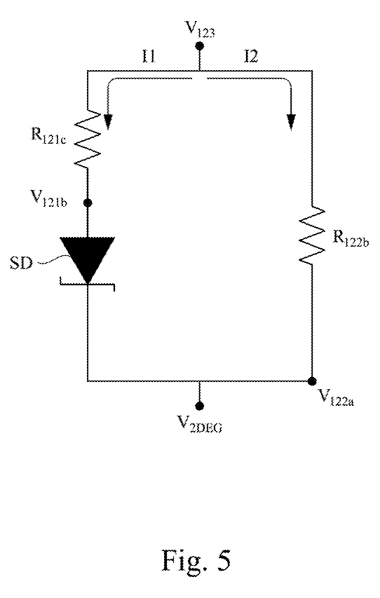

Reference is made to FIG. 1 to FIG. 5. FIG. 1 is a top view of a semiconductor device 10 according to some embodiments of the present disclosure. FIG. 2, FIG. 3, and FIG. 4 are partial cross-sectional views of the semiconductor device 10 along a line A-A’, a line B-B’, and a line C-C’ in FIG. 1, respectively. FIG. 5 is a schematic diagram of an equivalent circuit model of the semiconductor device 10.

As shown in FIG. 1, the semiconductor device 10 includes a substrate structure 100, a source structure 110, a drain structure 120, and a gate structure 130. The source structure 110, the drain structure 120, and the gate structure 130 are over a semiconductor layer 108 of the substrate structure 100 and arranged along a first direction D1. The gate structure 130 is between the source structure 110 and the drain structure 120. The source structure 110 and the gate structure 130 extend along a second direction D2. As shown in FIG. 1, the first direction D1 is substantially perpendicular to the second direction D2.

In some embodiments, the substrate structure 100 includes a semiconductor stack structure. For example, as shown in FIG. 2, FIG. 3, and FIG. 4, the substrate structure 100 includes a substrate 102, a buffer layer 104, a semiconductor layer 106, and a semiconductor layer 108. The buffer layer 104 is over the substrate 102. The semiconductor layer 106 is over the buffer layer 104. The semiconductor layer 108 is over the semiconductor layer 106. In some embodiments, the semiconductor layer 106 and the semiconductor layer 108 include III-V compound semiconductors. For example, the semiconductor layer 106 may include gallium nitride (GaN). The semiconductor layer 108 may include aluminum gallium nitride (AlGaN). As such, the semiconductor layer 106 and the semiconductor layer 108 form a heterojunction interface, which is characterized in a high density two-dimensional electron gas (2DEG) layer. Therefore, the semiconductor device 10 has lower energy consumption and higher power density than silicon-based semiconductor devices.

In some embodiments, the source structure 110 includes a source electrode 111, a plurality of source vias 112, and a source metal 113. As shown in FIG. 1, the source electrode 111 is a strip-shaped material extending along the second direction D2. The source vias 112 are over the source electrode 111 and arranged along the second direction D2. As shown in FIG. 2 and FIG. 3, the source metal 113 is over the source electrode 111 and electrically connected to the source electrode 111 through the source vias 112. In some embodiments, the materials of the source electrode 111 and the source metal 113 may include, but are not limited to, titanium, titanium nitride, aluminum, copper, or combinations thereof.

In some embodiments, the drain structure 120 includes a plurality of first electrode units 121, a plurality of second electrode units 122, and a drain metal 123. As shown in FIG. 1 and FIG. 4, the first electrode units 121 and the second electrode units 122 are arranged alternately along the second direction D2. In the top view, there is a gap G1 between one of the first electrode units 121 and one of the second electrode units 122 that is adjacent to the one of the first electrode units 121. Meanwhile, two adjacent ones of the first electrode units 121 are separated from each other and two adjacent ones of the second electrode units 122 are separated from each other, forming island-shaped structures. Detailed features of the first electrode units 121 and the second electrode units 122 will be described in subsequent paragraphs.

In some embodiments, the gate structure 130 includes a gate semiconductor layer 131 and a gate metal electrode 132. As shown in FIG. 1, the gate semiconductor layer 131 and the gate metal electrode 132 are strip-shaped materials extending along the second direction D2. As shown in FIG. 2 and FIG. 3, the gate metal electrode 132 is over the gate semiconductor layer 131. In some embodiments, the material of the gate semiconductor layer 131 includes, but is not limited to, gallium nitride or p-type doped gallium nitride. The material of the gate metal electrode 132 includes, but is not limited to, titanium, titanium nitride, aluminum, copper, or combinations thereof.

As shown in FIG. 2 and FIG. 4, each of the first electrode units 121 includes a p-type semiconductor layer 121a, a first metal electrode 121b over the p-type semiconductor layer 121a, and a first drain via 121c over the first metal electrode 121b. In some embodiments, the p-type semiconductor layer 121a is made of gallium nitride with p-type dopants. In some embodiments, the material of the first metal electrode 121b includes, but is not limited to, titanium, titanium nitride, aluminum, copper, or combinations thereof. The first metal electrode 121b is in contact with a top surface of the p-type semiconductor layer 121a to form a Schottky barrier diode (SBD). A length of the first metal electrode 121b is less than a length of the p-type semiconductor layer 121a, and a width of the first metal electrode 121b is less than a width of the p-type semiconductor layer 121a. A bottom surface of the p-type semiconductor layer 121a is in contact with the semiconductor layer 108. The first metal electrode 121b and the p-type semiconductor layer 121a are electrically connected to the drain metal 123 through the first drain via 121c.

As shown in FIG. 3 and FIG. 4, each of the second electrode units 122 includes a second metal electrode 122a and a second drain via 122b over the second metal electrode 122a. The second metal electrode 122a is in contact with the semiconductor layer 108 to form an ohmic contact. In some embodiments, the material of the second metal electrode 122a includes, but is not limited to, titanium, titanium nitride, aluminum, copper, or combinations thereof. The second metal electrode 122a is electrically connected to the drain metal 123 through the second drain via 122b.

Reference is made back to FIG. 1. A width W1 of the p-type semiconductor layer 121a of each of the first electrode units 121 along the first direction D1 is substantially equal to a width W2 of the second metal electrode 122a of each of the second electrode units 122 along the first direction D1. For example, the width W1 is between about 0.1 μm and about 3 μm. The width W2 is between about 0.1 μm and about 3 μm.

In some embodiments, a side face of the p-type semiconductor layer 121a of each of the first electrode units 121 (e.g., the side face of the p-type semiconductor layer 121a that is close to the gate structure 130) is coplanar with a side face of the second metal electrode 122a of each of the second electrode units 122 (e.g., the side face of the second metal electrode 122a that is close to the gate structure 130). In other words, in the top view, an edge of the p-type semiconductor layer 121a of each of the first electrode units 121 is flush with an edge of the second metal electrode 122a of each of the second electrode units 122. As such, the gate-drain length (L_{gd}, which is equivalent to a distance X1 and a distance X2 shown in FIG. 1) may be maximized, thereby reducing electric field spikes, providing a greater breakdown voltage, and improving device reliability.

In this case, the distance X1 between the side face of the p-type semiconductor layer 121a and the gate semiconductor layer 131 of the gate structure 130 along the first direction D1 is substantially equal to the distance X2 between the side face of the second metal electrode 122a and the gate semiconductor layer 131 along the first direction D1. It should be noted that both the distance X1 and the distance X2 are greater than a distance X3 between the source structure 110 and the gate structure 130. For example, the distance X1 is between about 0.3 μm and about 30 μm. The distance X2 is between about 0.3 μm and about 30 μm. The distance X3 is between about 0.1 μm and about 1 μm.

In some embodiments, the distance X1 is substantially equal to the distance X2. The width W1 is substantially equal to the width W2. Thus, a central axis of each of the first electrode units 121 coincides with a central axis of each of the second electrode units 122 and is parallel to the second direction D2. For example, the central axes of the first electrode units 121 and the central axes of the second electrode units 122 coincide with the line C-C’ in FIG. 1.

It should be noted that due to the limitation of fabrication processes, the second metal electrode 122a may be formed to be a structure that has a wider upper portion and a narrower lower portion (e.g., as the cross-sectional profile shown in FIG. 4). In this case, the width W2 and the distance X2 are measured based on the lower portion of the second metal electrode 122a. As such, a side face of the lower portion of the second metal electrode 122a is coplanar with the side face of the p-type semiconductor layer 121a. However, in the top view, an edge of the upper portion of the second metal electrode 122a may be not flush with the edge of the p-type semiconductor layer 121a.

In addition, as shown in FIG. 1, a length L1 of the p-type semiconductor layer 121a of each of the first electrode units 121 along the second direction D2 is less than a length L2 of the second metal electrode 122a of each of the second electrode units 122 along the second direction D2. For example, the length L1 is between about 0.1 μm and about 3 μm. The length L2 is between about 0.1 μm and about 30 μm. In greater detail, a sum of the lengths of the p-type semiconductor layers 121a of the first electrode units 121 of the drain structure 120 along the second direction D2 is less than a sum of the lengths of the second metal electrodes 122a of the second electrode units 122 of the drain structure 120 along the second direction D2. As such, as shown in FIG. 1, in the top view, an area of each of the second electrode units 122 is greater than an area of each of the first electrode units 121. Therefore, the area ratio for which each of the second electrode units 122 accounts in the top view is increased, thereby reducing the on-resistance of each of the second electrode units 122.

Reference is then made to FIG. 4. The first electrode units 121 and the second electrode units 122 are arranged alternately and spaced apart along the second direction D2 and are connected to the drain metal 123. In the cross-sectional view taken along the line C-C’, the second metal electrode 122a of each of the second electrode units 122 has the lower portion and the upper portion connected to the lower portion as aforementioned. The lower portion of the second metal electrode 122a is in direct contact with the semiconductor layer 108. The upper portion of the second metal electrode 122a is over the lower portion and in contact with the second drain via 122b. As shown in FIG. 1 and FIG. 4, there is a gap G1 between the edge of the upper portion of the second metal electrode 122a of one of the second electrode units 122 and the edge of the p-type semiconductor layer 121a of one of the first electrode units 121. In other words, an orthographic projection area of the second metal electrode 122a of the one of the second electrode units 122 projected onto the substrate structure 100 and an orthographic projection area of the p-type semiconductor layer 121a of the one of the first electrode units 121 projected onto the substrate structure 100 are separated from each other and do not overlap. In addition, in some embodiments, as shown in FIG. 4, a top surface of the upper portion of the second metal electrode 122a is higher than a top surface of the first metal electrode 121b. In other words, a bottom end of the second drain via 122b is higher than a bottom end of the first drain via 121c.

Under such configuration, the first electrode units 121 and the second electrode units 122 are spaced apart and electrically connected to the drain metal 123 through the first drain vias 121c and the second drain vias 122b, respectively. As a result, in a conducting state, the first metal electrode 121b of each of the first electrode units 121 and the second metal electrode 122a of each of the second electrode units 122 may have different potentials. To be more specific, referring to FIG. 5, current may flow from the drain metal 123, which has a potential value V₁₂₃, to the two-dimensional electron gas layer, which has a potential value V_{2DEG}, via two paths. The path shown on the left of FIG. 5 passes through the first drain via 121c and the Schottky barrier diode SD formed by the first metal electrode 121b and the p-type semiconductor layer 121a. The path on the right of FIG. 5 passes through the second drain via 122b and the second metal electrode 122a. Therefore, a potential value V_{121b} of the first metal electrode 121b and a potential value V₁₂₂ₐ of the second metal electrode 122a may be different. As such, when a resistance value R_{121c} of the first drain via 121c of each of the first electrode units 121 is greater than a resistance value R_{122b} of the second drain via 122b of each of the second electrode units 122, a current value I1 of current flowing through the path on the left is less than a current value I2 of current flowing through the path on the right. Hence, the energy consumption of each of the first electrode units 121 may be reduced. In addition, the first drain via 121c serves as a protection resistor that may suppress voltage overshoot caused by abnormal disturbance of the drain metal 123 and avoid damage to the Schottky barrier diode SD.

Next, a method for forming the semiconductor device 10 according to some embodiments of the present disclosure will be described accompanied with FIG. 1 and FIG. 4. First, the substrate structure 100 is provided. For example, the buffer layer 104, the semiconductor layer 106, and the semiconductor layer 108 are sequentially formed on the substrate 102. Next, the p-type semiconductor layers 121a are formed separated from each other and arranged along the second direction D2 over the substrate structure 100. In some embodiments, the gate semiconductor layer 131 of the gate structure 130 may be formed simultaneously in this step. Next, the first metal electrodes 121b are formed over the p-type semiconductor layers 121a, respectively. In some embodiments, the gate metal electrode 132 of the gate structure 130 may be formed simultaneously in this step. Next, the second metal electrodes 122a are formed between every two adjacent ones of the p-type semiconductor layers 121a, so that the p-type semiconductor layers 121a and the second metal electrodes 122a are arranged alternately along the second direction D2. Meanwhile, the width W2 of each of the second metal electrodes 122a along the first direction D1 is substantially equal to the width W1 of each of the p-type semiconductor layers 121a along the first direction D1. In some embodiments, the source electrode 111 of the source structure 110 may be formed simultaneously in this step. Next, the first drain vias 121c and the second drain vias 122b are formed over the first metal electrodes 121b and the second metal electrodes 122a, respectively. In some embodiments, the source vias 112 of the source structure 110 may be formed over the source electrode 111 simultaneously in this step. Next, the drain metal 123 is formed over the first drain vias 121c and the second drain vias 122b. In some embodiments, the source metal 113 may be formed over the source vias 112 simultaneously in this step.

In some embodiments, the second metal electrodes 122a are formed such that in the top view, there is a gap G1 between one of the p-type semiconductor layers 121a and one of the second metal electrodes 122a that is adjacent to the one of the p-type semiconductor layers 121a along the second direction D2.

In some embodiments, after the first metal electrodes 121b are formed, a dielectric layer may be formed covering top surfaces of the first metal electrodes 121b, the p-type semiconductor layers 121a, and the substrate structure 100. Then, forming the second metal electrodes 122a includes forming openings that expose the top surface of the substrate structure 100 in the dielectric layer and forming the second metal electrodes 122a in the openings, respectively.

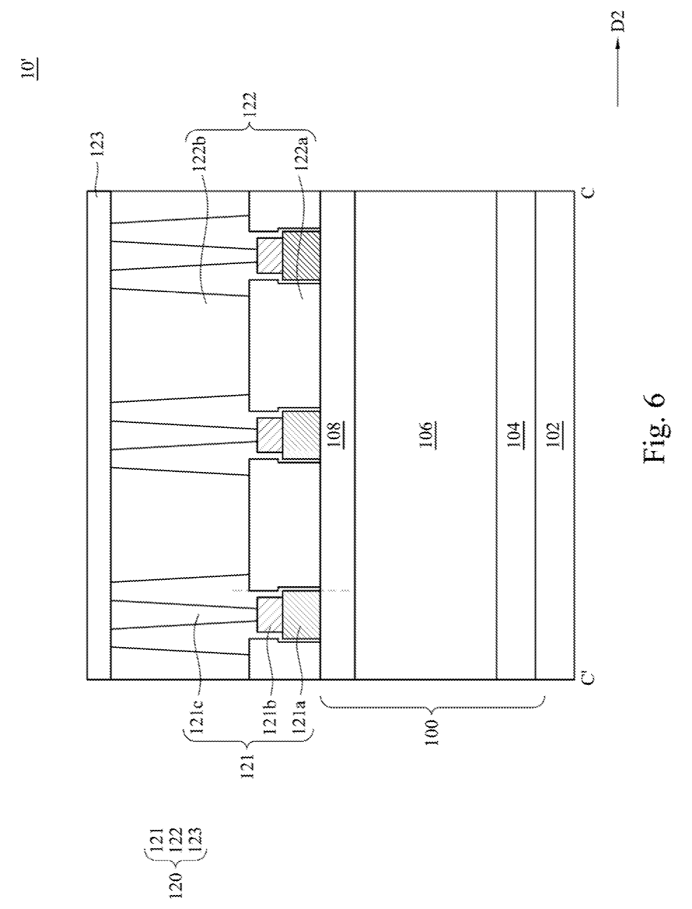

In some other embodiments, the gap G1 may be zero-distance. For example, reference is made to FIG. 6. FIG. 6 is a partial cross-sectional view of a semiconductor device 10′ according to some other embodiments of the present disclosure. The difference between the semiconductor device 10’ and the semiconductor device 10 is that an orthographic projection area of the second metal electrode 122a of one of the second electrode units 122 of the semiconductor device 10’ projected onto the substrate structure 100 and an orthographic projection area of the p-type semiconductor layer 121a of one of the first electrode units 121 of the semiconductor device 10’ projected onto the substrate structure 100 are connected to each other and do not overlap. In greater detail, as shown in FIG. 6, an edge of the upper portion of the second metal electrode 122a of the one of the second electrode units 122 and an edge of the p-type semiconductor layer 121a of the one of the first electrode units 121 are aligned with a dotted line that is perpendicular to the top surface of the substrate structure 100 in FIG. 6. Meanwhile, each of the second metal electrodes 122a and each of the p-type semiconductor layers 121a are separated from each other. On the other hand, in the top view, the edge of the upper portion of the second metal electrode 122a of the one of the second electrode units 122 coincides with the edge of the p-type semiconductor layer 121a of the one of the first electrode units 121. As such, the area ratio for which the second electrode units 122 account in the top view may be further increased.

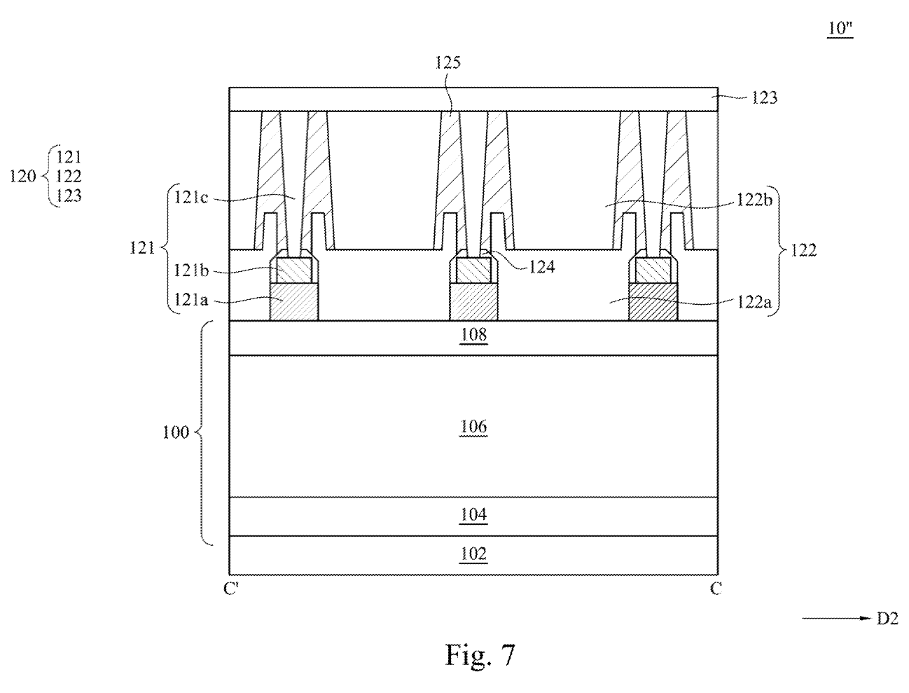

In still some other embodiments, an orthographic projection area of the second metal electrode 122a of one of the second electrode units 122 projected onto the substrate structure 100 overlaps an orthographic projection area of the p-type semiconductor layer 121a of one of the first electrode units 121 projected onto the substrate structure 100. For example, reference is made to FIG. 7. FIG. 7 is a partial cross-sectional view of a semiconductor device 10” according to still some other embodiments of the present disclosure. The difference between the semiconductor device 10” and the semiconductor device 10 is that the semiconductor device 10” further includes a dielectric layer 124 and a planarization layer 125, and an orthographic projection area of the second metal electrodes 122a projected onto the substrate structure 100 overlaps an orthographic projection area of the p-type semiconductor layers 121a projected onto the substrate structure 100. In greater detail, the dielectric layer 124 covers the first metal electrodes 121b and the p-type semiconductor layers 121a. The lower portions of the second metal electrodes 122a are in contact with side walls of the dielectric layer 124 and the p-type semiconductor layers 121a. The upper portions of the second metal electrodes 122a extend over the dielectric layer 124 and are in contact with the dielectric layer 124. In other embodiments, the lower portions of the second metal electrodes 122a of the semiconductor device 10” may be in contact with top surfaces of the p-type semiconductor layers 121a but may still be separated from the side walls of the first metal electrodes 121b through the dielectric layer 124.

Correspondingly, in the method for forming the semiconductor device 10”, after the first metal electrodes 121b are formed, the dielectric layer 124 is formed covering the top surfaces of the first metal electrodes 121b, the p-type semiconductor layers 121a, and the substrate structure 100. Then, openings that expose the top surface of the substrate structure 100 are formed in the dielectric layer 124, and the second metal electrodes 122a are formed in the openings, respectively. Next, after the second metal electrodes 122a are formed, the planarization layer 125 is formed covering the second metal electrodes 122a and the dielectric layer 124, and some other openings are formed in the planarization layer 125 and the dielectric layer 124 for forming the first drain vias 121c and the second drain vias 122b in subsequent processes.

According to the foregoing recitations of the embodiments of the disclosure, it may be seen that in some embodiments of the semiconductor device of the present disclosure, the first electrode units and the second electrode units of the drain structure are arranged alternately. Each of the first electrode units includes the first metal electrode and the p-type semiconductor layer that form a Schottky barrier diode. Each of the second electrode units includes the second metal electrode that forms an ohmic contact with the underlying semiconductor layer. Meanwhile, the width of the p-type semiconductor layer of each of the first electrode units along the first direction is substantially equal to the width of the second metal electrode of each of the second electrode units along the first direction, and the distance between the p-type semiconductor layer of each of the first electrode units and the gate structure along the first direction is substantially equal to the distance between the second metal electrode of each of the second electrode units and the gate structure along the first direction, in which the first direction is substantially perpendicular to the arranging direction of the first electrode units and the second electrode units. As such, the gate-drain length may be maximized, thereby reducing electric field spikes, providing a greater breakdown voltage, and improving device reliability.

What is claimed is:

1. A semiconductor device, comprising:
a substrate structure comprising a semiconductor layer;
a source structure over the semiconductor layer of the substrate structure;
a drain structure over the semiconductor layer and arranged along a first direction with the source structure, wherein the drain structure comprises:
a plurality of first electrode units, wherein each of the first electrode units comprises a p-type semiconductor layer and a first metal electrode over the p-type semiconductor layer; and
a plurality of second electrode units, wherein each of the second electrode units comprises a second metal electrode,
wherein the first electrode units and the second electrode units are arranged alternately along a second direction, and the second direction is substantially perpendicular to the first direction,
wherein a width of the p-type semiconductor layer of each of the first electrode units along the first direction is substantially equal to a width of the second metal electrode of each of the second electrode units along the first direction; and
a gate structure over the semiconductor layer and between the source structure and the drain structure.

2. The semiconductor device of claim 1, wherein a side face of the p-type semiconductor layer of each of the first electrode units is coplanar with a side face of the second metal electrode of each of the second electrode units.

3. The semiconductor device of claim 2, wherein a distance between the side face of the p-type semiconductor layer and the gate structure along the first direction is substantially equal to a distance between the side face of the second metal electrode and the gate structure along the first direction.

4. The semiconductor device of claim 1, wherein a central axis of each of the first electrode units coincides with a central axis of each of the second electrode units and is parallel to the second direction.

5. The semiconductor device of claim 1, wherein a length of the p-type semiconductor layer of each of the first electrode units along the second direction is less than a length of the second metal electrode of each of the second electrode units along the second direction.

6. The semiconductor device of claim 1, wherein each of the first electrode units and each of the second electrode units are separated from each other.

7. The semiconductor device of claim 6, wherein an orthographic projection area of the p-type semiconductor layer of each of the first electrode units projected onto the substrate structure is separated from an orthographic projection area of the second metal electrode of each of the second electrode units projected onto the substrate structure.

8. The semiconductor device of claim 6, wherein an orthographic projection area of the p-type semiconductor layer of one of the first electrode units projected onto the substrate structure and an orthographic projection area of the second metal electrode of one of the second electrode units projected onto the substrate structure are connected to each other and do not overlap.

9. The semiconductor device of claim 1, wherein an orthographic projection area of the p-type semiconductor layer of one of the first electrode units projected onto the substrate structure overlaps an orthographic projection area of the second metal electrode of one of the second electrode units projected onto the substrate structure.

10. The semiconductor device of claim 9, wherein the second metal electrode of the one of the second electrode units extends to be in contact with the p-type semiconductor layer of the one of the first electrode units.
